(19) United States
(12) Patent Application Publication
(10) Pub. No.: US 2022/0200637 A1
(43) Pub. Date: Jun. 23, 2022

(54) HIGH-PERFORMANCE FILTER BANK CHANNELIZERS

(71) Applicant: Spectral DSP Corp, New York, NY (US)

(72) Inventor: Fredric J. Harris, San Diego, CA (US)

(21) Appl. No.: 17/559,834

(22) Filed: Dec. 22, 2021

Related U.S. Application Data
(60) Provisional application No. 63/129,980, filed on Dec. 23, 2020.

(51) Int. Cl. H04B 1/00; H04B 1/38; H04B 1/04; H04B 1/7093

(52) U.S. Cl. CPC H04B 1/0014; H04B 1/38; H04B 2001/70935; H04B 1/7093; H04B 1/0483

(57) ABSTRACT

High-performance filter bank channelizers are provided. In one embodiment, a heterodyne signal shifts an input spectrum of the input signal by an offset between input and output centers, and operates at a high input sample rate. In another embodiment, the channelizer includes an input commutator receiving and commutating an input signal, an M-path polyphaser filter in communication with the commutator, and an M-path inverse discrete Fourier transform module processing outputs of the polyphaser filter, wherein the M-path polyphaser filter introduces a plurality of phase rotations in a time domain resulting in a workload reduction for a processor on which the channelizer is implemented. Still other embodiments includes a resampling channelizer, a half-band filter, and a cascaded half-band filter.

### RELATED APPLICATIONS

This application claims priority to U.S. Provisional Patent Application Ser. No. 63/129,980 filed on Dec. 23, 2020, the entire contents of which is expressly incorporated by reference herein.

### TECHNICAL FIELD

The present disclosure relates generally to the field of signal processing. More particularly, the present disclosure relates to high-performance filter bank channelizers.

### RELATED ART

The M-path polyphase analysis filter bank channelizer is quite a remarkable digital signal processing technology. In its simplest realization, the maximally decimated filter bank, the bank outputs M baseband time series from translated spectral spans with bandwidth and sample rate fₛ/M from M spectral bands centered at integer multiples of fₛ/M. Modifications to the channelizer are many and include offsets of channelizer center frequencies, non-maximal decimation from M-to-1 to M/2-to-1 or to 3M/4-to-1 along with various post channelization signal conditioning options.

While filter bank channelizers are of significant use and importance in the digital signal processing field, it would be beneficial to improve the performance of such channelizers by reducing the amount of computational processing that must be carried out by digital signal processors and other devices on which such channelizers are implemented. Doing so would significantly improve the performance and speed of such channelizers. Accordingly, what would be desirable are high-performance filter bank channelizers which address the foregoing, and other, needs.

### SUMMARY

The present disclosure relates to high-performance filter bank channelizers. In one embodiment, a high-performance channelizer is provided which includes a digital direct synthesis (DDS) module generating a heterodyne signal; a mixer in communication with DDS module and mixing the heterodyne signal with an input signal; and an M-path channelizer in communication with the mixer, the M-path channelizer processing an output signal of the mixer to generate a plurality of output channels, wherein the heterodyne signal shifts an input spectrum of the input signal by an offset between input and output centers. The heterodyne signal operates at a high input sample rate.

In another embodiment, a high-performance channelizer is provided which includes an input commutator receiving and commutating an input signal; an M-path polyphaser filter in communication with the commutator; and an M-path inverse discrete Fourier transform module processing outputs of the polyphaser filter, wherein the M-path polyphaser filter introduces a plurality of phase rotations in a time domain resulting in a workload reduction for a processor on which the channelizer is implemented. The plurality of phase rotations can be inserted at a rate of 1/30th of an input rate of the channelizer.

In another embodiment, a resampling channelizer is provided and includes a frequency division multiplex (FDM) commutator receiving and commutating an FDM input signal; an M/2-path input data buffer in communication with the FDM commutator; an M-path polyphaser filter in communication with the input data buffer; a circular output buffer in communication with the M-path polyphaser filter; an M-point inverse fast Fourier (IFFT) module in communication with the circular output buffer; and a time division multiplex (TDM) commutator in communication with the M-point IFFT module and generating a TDM output signal, wherein the M-path polyphaser filter is operated at a sample rate above fₛ/M.

In still another embodiment, a half-band filter is provided, and includes an upper filter path including even indices of a low-pass filter; a lower filter path including even symmetric filter coeeficients; a switch in communication with the upper and lower filter paths and switching an input signal between the upper and lower filter paths; and a mixer in communication with the upper and lower filter paths and mixing outputs of the upper and lower filter paths.

In yet another embodiment, a cascaded half-band filter is provided, and includes an input commutator receiving and commutating an input signal; a first M-path filter in communication with the input commutator; a first M-point circular buffer in communication with the first M-path filter; a first M-point inverse fast Fourier transform (IFFT) module in communication with the first M-point circular buffer; a second M-point IFFT module in communication with the first IFFT module; a second M-point circular buffer in communication with the second M-point IFFT module; a second M-path filter in communication with the second M-point circular buffer; and an output commutator in communication with the second M-path filter and generating an output signal, wherein the input commutator, the first M-path filter, the first M-point circular buffer, and the first M-point IFFT module form an analysis channelizer, and the second M-point IFFT module, the second M-point circular buffer, the second M-path filter, and the output commutator form a synthesis channelizer, the analysis channelizer cascaded with the synthesis channelizer.

### BRIEF DESCRIPTION OF THE DRAWINGS

The foregoing features of the invention will be apparent from the following Detailed Description of the Invention, taken in connection with the accompanying drawings, in which:

FIG. 1 is a diagram illustrating a standard M-path polyphase channelizer, including an M-port commutator, an M-path polyphase filter, and an M-point inverse fast Fourier transform (IFFT);

FIG. 2 is a diagram illustrating a spectral description of a multi-channel signal presented to a 30-path maximally decimated polyphase filter band;

FIG. 3 is a diagram illustrating a spectrum of a 30-channel channelizer filter with zoom to passband ripple and transition bandwidth;

FIG. 4 is a diagram illustrating complex heterodyne alignment of spectral centers of input signals with spectral centers of channelizer channels;

FIG. 5 is a diagram illustrating a modified M-path polyphase channelizer, including an M-port commutator, an M-path polyphase filter, frequency offset rotators, and an M-point IFFT;

FIG. 6 is a diagram illustrating an M-path, M/2-to-1 down sample polyphase analysis filter architecture;

FIG. 7 is a diagram illustrating frequency response of a widest transition bandwidth (BW) filter for a 48 MHz output sample rate channelizer;

FIG. 8 is a diagram illustrating frequency response of narrower transition bandwidth (BW) filter for a 48 MHz output sample rate channelizer;

FIG. 9 is a diagram illustrating a spectrum of a 30-channel channelizer filter with zoom to passband ripple and wider transition bandwidth;

FIG. 10 is a diagram illustrating a spectrum of a true half band finite impulse response (FIR) filter with zoom to passband ripple and desired transition bandwidth;

FIG. 11 is a block diagram of a two path 2-to-1 down-sample half band filter;

FIG. 12 is a diagram illustrating impulse response and spectrum of true half band infinite impulse response (IIR) all-pass filter with zoom to passband ripple and desired transition bandwidth;

FIG. 13 is a diagram illustrating a cascade of analysis and synthesis channelizers with super channel passband formed by the binary mask between the pair; and

FIG. 14 is a diagram illustrating spectral characteristics of a half band super channel formed by cascade analysis and synthesis channelizers.

### DETAILED DESCRIPTION

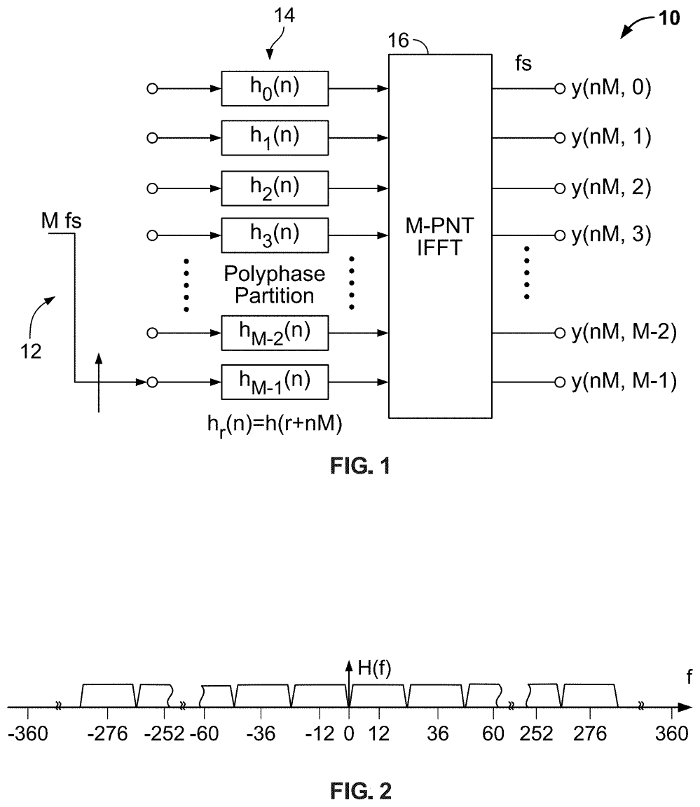

The present disclosure relates to high-performance filter bank channelizers, as described in detail below in connection with FIGS. 1-14.

In its most common incarnation, a polyphase down sampling channelizer simultaneously down converts and down samples M equally spaced, fixed bandwidth signals. FIG. 1 shows the channelizer structure 10, including an M-port commutator 12, an M-path partitioned low-pass prototype filter 14, and an M-point inverse discrete Fourier transform (IDFT) 16. For computational efficiency, the IDFT is implemented with the IFFT algorithm. In this configuration, the commutator 12 delivers M consecutive samples to the M input ports of the M-path filter 14. Each port receives a data sequence sampled at fₛ/M with successive one-sample time delay offsets in successive paths. The sample rate reduction causes M-fold spectral aliases of the input spectrum, an effect easily observed in the frequency domain. The time series of each aliased band have an output sample rate of fₛ/M. In each arm, every spectral band centered at the M multiples of the output sample rate alias to the base band span centered at direct current (DC). The alias terms in each arm have distinct phase profiles due to their distinct center frequencies and the different delays of the sampled time series delivered to each commutator port. In particular, each of the aliased terms exhibits a phase shift equal to the product of its center frequency k with its path time delay rTₛ. These phase shifts are shown in Equation (1) below, where fₛ is the sample rate at the input to the polyphase filter and Tₛ, its reciprocal, is the time interval between input samples:

$$ϕ ( r , k ) = - {ω}_{k} Δ {T}_{f} = - 2 π \frac{{f}_{s}}{M} {krT}_{s} = - \frac{2 π}{M} rk \qquad ( 1 )$$

The time delay response of each path filter aligns the time origin of their sampled data sequences formed at their outputs to a single common output time origin. This task is accomplished by the all-pass characteristics of the M-path partitioned filter that apply the required differential time delay to the individual input time series. Finally, the IFFT block performs the equivalent of a beam-forming operation; the coherent summation of the time aligned signals at each output port with selected phase profile. Note that the channel spacing, the channel bandwidth, and the sample rate are all fₛ/M. This form of the channelizer is called a maximally decimated filter bank.

As a multi-channel channelizer in which we extract and separate adjacent channels, the signal bandwidth must be less than the channel spacing. Under this condition, there is spectral gap between the input channel bands. The gap is required for the channel filters to have a non-zero transition bandwidth between the channel bands. Discussed below are the signal bandwidths and channel spacing , as well as the required filter characteristics. Also discussed below is the option of increasing the transition bandwidth of the channelizer and follow the channelizer with filters that form the desired narrow transition bandwidth. Because these filters operate at the reduced output sample rate, their reduced length and clock speed offer significant implementation advantages.

FIG. 2 presents an illustration of the multi-channel input spectra to be processed by the filter bank disclosed herein. A quick description of this signal set is that there are 24 bands spanning 576 MHz, sampled at 720 MHz. The band centers are symmetric about direct current (DC), with bandwidths slightly narrower than 24 MHz, and separated by 24 MHz centers. The required performance specification of the channel filter is that the 0.1 dB ripple bandwidth is 23.0 MHz and the −50 dB stopband bandwidth is 24 MHz. The number of paths in the polyphase filter and the IFFT size is determined by the ratio of input sample rate to output sample rate, a relationship shown in Equation (2) below:

$$Output Sample Rate {f}_{Ox} = \frac{Input Sample Rate {f}_{1 x}}{M} \qquad ( 2 )$$

The expression to determine the number of taps in a finite impulse response (FIR) filter is shown in Equation (2) where fₛ is sample rate , Δf is transition bandwidth and K(A) is a parameter proportional to A, the out of band attenuation level. The estimate from Equation (2) sets the filter length to 3273 taps. When designed by the FIRPM algorithm the estimate proved to be very good. We adjusted the filter length to be 1 less than the closest multiple of 30, a filter of length 3269 taps which met the design specifications. When partitioned into the 30 arms of the 30 path polyphase filter we find each arm contains 109 taps:

$$N = \frac{{f}_{s}}{Δ f} K ( A ) ≅ \frac{{f}_{s}}{Δ f} \frac{Atten ( dB )}{22} \qquad ( 3 )$$

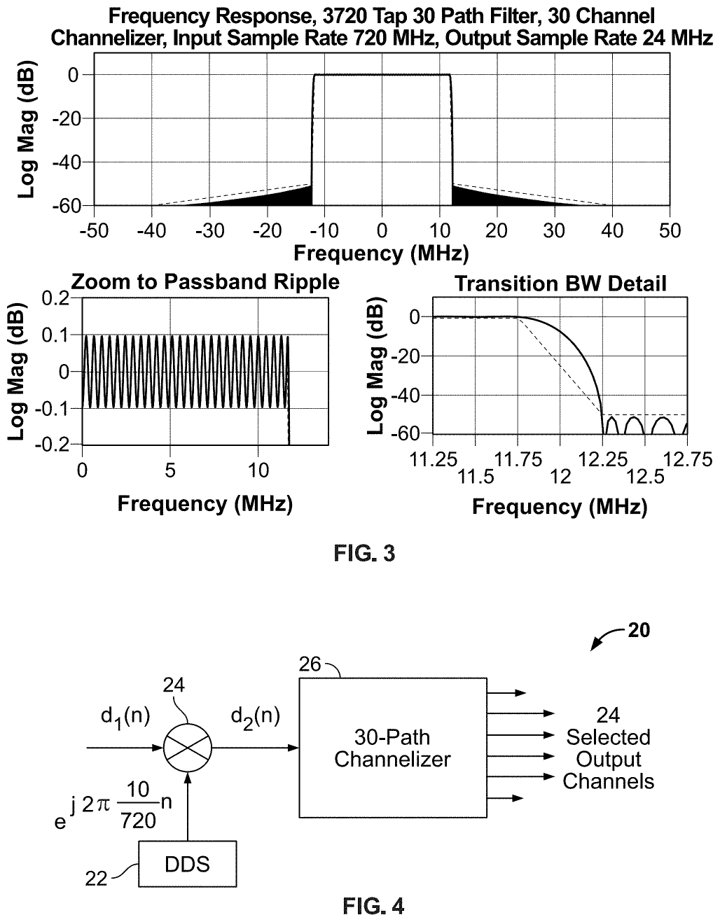

We can implement the 30 path filters of the channelizer with each path operating at 1/30th of the input rate 720 MHz/30 or 24 MHz, a comfortable speed for an FPGA implementation. We simulated the design in MATLAB, and the spectral responses of the prototype filter are shown in FIG. 3. A minor problem is the filter centers of the channelizer are offset 12 MHz from the channel centers of the input signal. One solution to this problem is to use a complex heterodyne between the input signal and the channelizer to shift the input spectrum the 12 MHz offset between the input and output centers. This heterodyne, operating at the high input sample rate is shown in FIG. 4. Specifically, as shown in FIG. 4, the channelizer 20 includes a direct digital synthesis module 22 that produces a heterodyne signal, a mixer 24 that mixes the heterodyne signal with the input signal, and a 30-path channelizer 26 that generates output channels.

The rotator sequence is periodic in twice the length of the output vectors formed by the polyphase filter. Noting the sign change at the midpoint of the rotator vector we apply the rotators to the filter output in the same way the lower half of the butterfly of a radix-2 FFT forms its sum. We form the weighted sum of the even indexed data vectors and the weighted sum of the odd indexed data vectors and apply the complex rotator weights to their difference. Alternate vector outputs have to be sign changed to keep the channel spectral bin center at direct current (DC) rather than at the half sample rate.

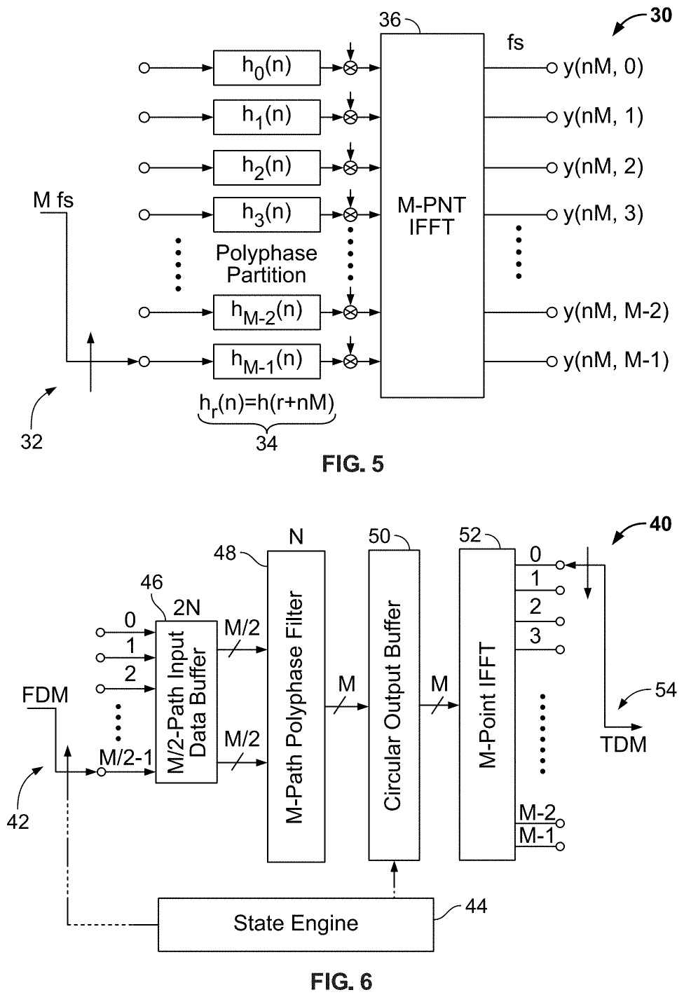

The modified form of the channelizer incorporating the half band width frequency offset discussed above is shown in FIG. 5. As can be seen, the channelizer 30 includes an M-port (input) commutator 32, an M-path polyphaser filter 34, and an M-point inverse discrete Fourier transform (IDFT) 16 that can be implemented using an IFFT algorithm for computational efficiency. The filter 34 generates phase rotation corrections inserted between the polyphase filter output and the IFFT input of the IDFT 16. Importantly, the phase rotations introduced by the filter 34 result in important workload reductions for a digital signal processor (DSP) or other processor on which the channelizer 30 is implemented. Rather than apply the frequency shift phase rotations in the time domain at the high input rate, they are inserted into the polyphase filter and applied at the IFFT rate which is 1/30th of the input rate.

We now consider a modification to the channelizer that holds promise of reduced workload but still meets the design requirements. We recognize that the workload in the channelizer is dominated by the large number of coefficients in the polyphase filter partition. As commented on earlier, in (2), this number is large because the ratio of sample rate to transition bandwidth is large. We can reduce the channelizer computational workload if we increase the transition bandwidth. This would reduce the filter length but would result in a filter that doesn't meet the design requirements. Our response to this problem is we use a second filter applied to the channelizer output to form the reduced transition bandwidth at reduced cost because of its reduced sample rate.

If we increase the transition bandwidth of the channelizer filter we will also have to increase the output sample rate of the channelizer. We present a modified version of the Nyquist theorem. The Nyquist criterion tells us that the sample rate should exceed the two sided bandwidth, leaving the question: “By how much?” The channelizers disclosed herein answer that question. As shown in Equation (4) below, we should exceed the signal's two sided BW by the transition BW of the anti-alias filters.

Nyquist: fₛ>2 Sided BW

harris: fₛ=2 sided BW+Filter Transition BW (4)

The excess bandwidth typically increases the filter sample rate (fₛ) by 10% to 20%. In the modern era, we raise the sample rate to accommodate a significant increase in transition BW and then use a follow-up DSP filters to reduce the bandwidth and sample rate to the desired lower values.

When we run the M path polyphase filter bank at rates above fₛ/M, the architecture changes and the channelizer is known as non-maximally decimated filter bank. We have a few options for the amount to raise the output sample rate. One common and easy to implement options is to double the sample rate from fₛ/M to 2 fₛ/M. For our particular example we raise the output sample rate from fₛ/30 or 720/30 or 24 MHz to 720/15 or 48 MHz by delivering 15 samples to the channelizer and form 30 output samples for every 15 input samples. We could have selected some other ratio which increased the sample rate by a smaller amount such as 720/20 or 36 MHz by delivering 20 samples to the channelizer and form 30 output samples for every 20 input samples. In the first case we would increase the sample rate by 100% and in the second we would increase the sample rate by 50%. The option space for the first case is quite wide. Whichever choice we would finally select, we would be sure to include the internal frequency shift option in the resampled channelizer. The common configuration of the M/2-to-1 resampling channelizer is shown in FIG. 6. The resampling channelizer (indicated at 40) includes a frequency-division multiplex (FDM) commutator 42 receiving and commutating an FDM input signal and controlled by a state engine 44, an M/2-path input data buffer 46, an M-path polyphaser filter 48, a circular output buffer 50 (also controlled by the state engine 44), an M-point IFFT 52, and a time division multiplex (TDM) commutator 54 generating a TDM output signal. The output sample rate here would be 48 MHz. The polyphaser filter 48 is operated at a rate above fₛ/M.

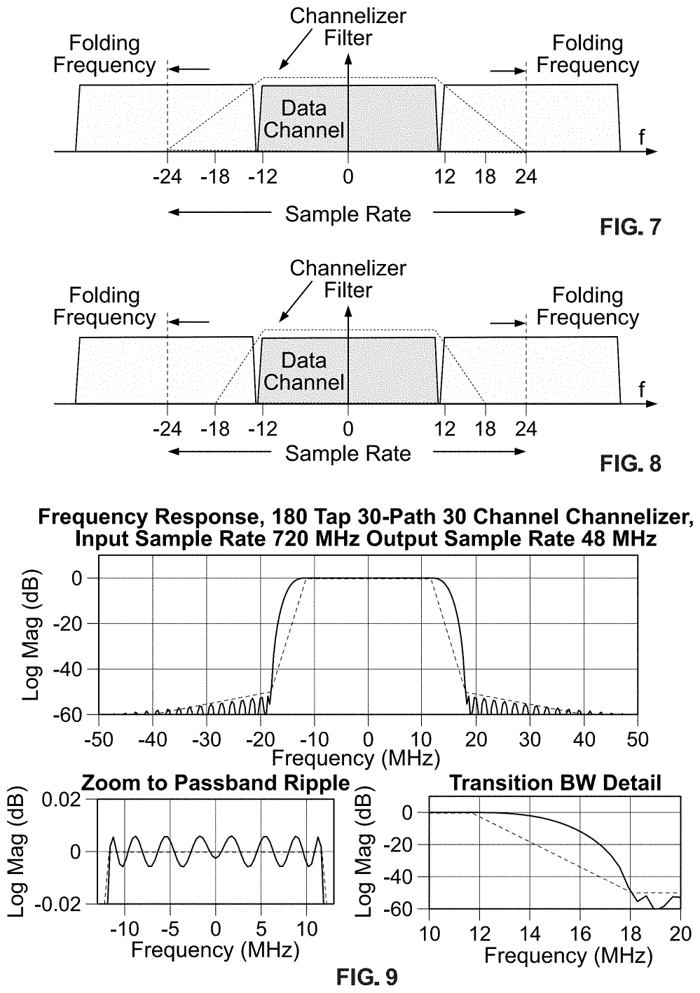

FIG. 7 shows the spectral response of the widest possible, alias free, transition bandwidth we could use at the 48 MHz output sample rate. This increase in transition BW from 0.5 MHz to 12 MHz would reduce the channelizer filter length by a factor of 48-to-1. The length would go from 109 samples per path to 3 sample per path after rounding up to the nearest integer. The problem with this transition BW filter is we can't easily demonstrate the out-of-band spectral rejection of the channelized baseband filter. Thus, for demonstration purpose, we design the channelizer filter to satisfy the spectral response shown in FIG. 8, a filter with transition BW of 6 MHz The 30-path channelizer filter will have 6 samples per path, still a significant reduction from 109 samples per path.

We designed the 30 path channelizer to meet the specifications indicated in FIG. 8. The spectral responses of that design are shown in FIG. 9. The first significant difference we see here, besides the wider transition BW, is the order of magnitude reduction of the in-band ripple. We designed the filter for a reduced level of in-band ripple because the channelized baseband series will be passed through a second filter which will add its in-band ripple levels to the channelizer ripple. The next matter for us to explore is that follow-up house cleaning filter.

We now have the task of designing the cascade filter that will reduce the transition bandwidth of channelized time series to the desired 0.5 MHz. It would be nice if that filter be configured to reduce the sample rate from 48 MHz to 24 MHz. The first filter option that comes to mind is a true half-band finite impulse response (FIR) filter. Access to this option is why we selected 48 MHz for the channelizer output sample rate. The qualifier, true for the half band filter, is that we want the design to have zero value on alternate output samples. We can achieve that goal with a windowed sinc series or with the half-band technique that uses the FIRPM algorithm to design the filter's odd index non-zero weights and inserting the even index zeros and center tap. The former design is characterized by non-uniform pass band and stop band ripple levels while the later has the equal ripple response of the standard FIRPM design.

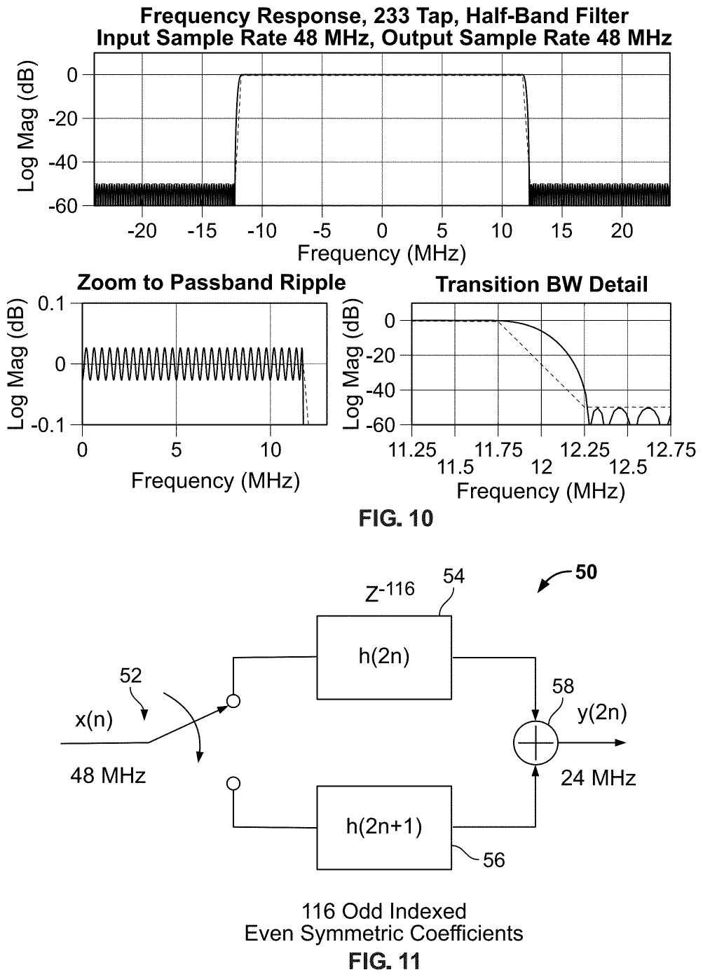

We selected the half-band technique and designed the half band filter to operate at the 48 MHz sample rate with the desired 0.5 MHz transition BW and the 50 dB stopband levels. The filter length require to meet these requirements is 233 taps and the spectral characteristics of the filter is shown in FIG. 10. Note the half band filter has the same value in-band and out-of-band ripple levels. Consequently, the in-band ripple is approximately 0.03 dB, the same deviation from unity gain that -50 dB is a deviation from 0. The combined ripple of the channelizer and its cascade filter we easily meet the 0.1 dB requirement. FIG. 11 shows the block diagram of a 2-path, 2-to-1 down sample half band filter 50. The upper path 54 contains the even indices of the low pass filter. These are the inserted zeros of the design process and thus has only 1-non-zero, trivial valued coefficient offset to the filter center sample. The lower path 56 contains 116 even symmetric filter coefficients. The input signal is switched between the upper path 54 and the lower path 56 by a switch 52, and the outputs of the upper and lower paths 54, 56 are mixed by a mixer 58 to produce the output signal. When the filter are folded to share the weights, the lower path has 58 multiplies. These 58 multiplies are performed every time 2 samples are delivered to the filter, so the filter workload is 29 multiplies per input sample. This work is performed at the 48 MHz clock rate which if referred back to the 15 times higher, 720 MHz input clock would be equivalent to approximately 2 multiplies per input sample. Of course we are performing this task 24 times, once for each output channel.

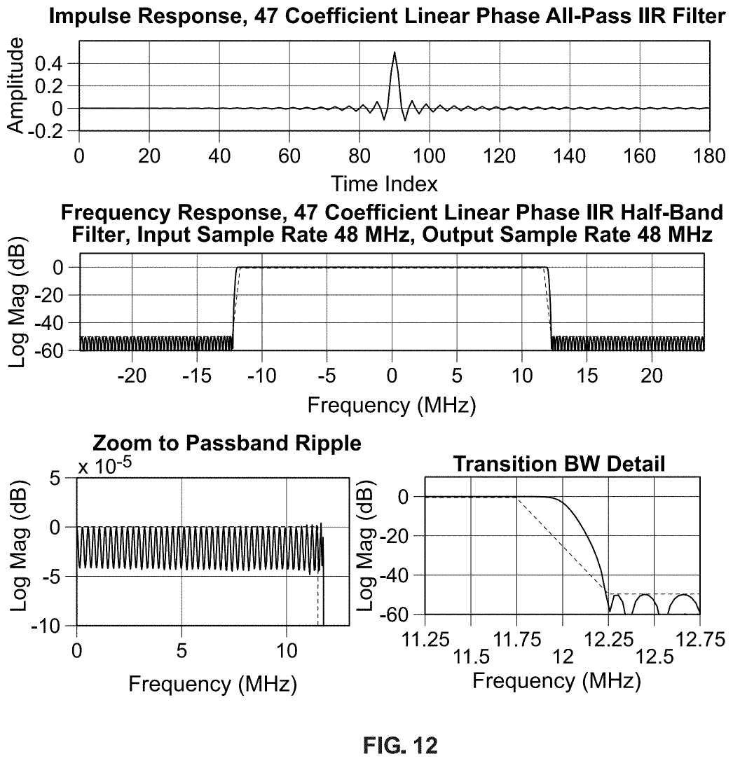

A second option for the half-band filter is a linear phase all-pass infinite impulse response (IIR) filter. We designed and simulated the IIR version of the half band filter which has a 2-to-1 down sampling option implementation very similar to that of FIG. 11. This filter using a cascade of 1st and 2nd order all-pass polynomial in Z2 required 1-first order filter with one coefficient and 23-second order filters with 2-coefficients, for a total of 47-coefficients to implement the IIR version. FIG. 12 shows the impulse response and spectral characteristics of this option. The impulse response of the linear phase IIR filter with its shorter causality delay is definitely interesting. The other interesting characteristic of this filter is the extremely low level of in-band ripple, slightly below 50 μdB. Like the FIR half band filter, the IIR version performs its 47 multiplies for every 2-input samples which results in less than 24 multiplies per input sample which gives this filter a slight lead relative to the FIR filter option.

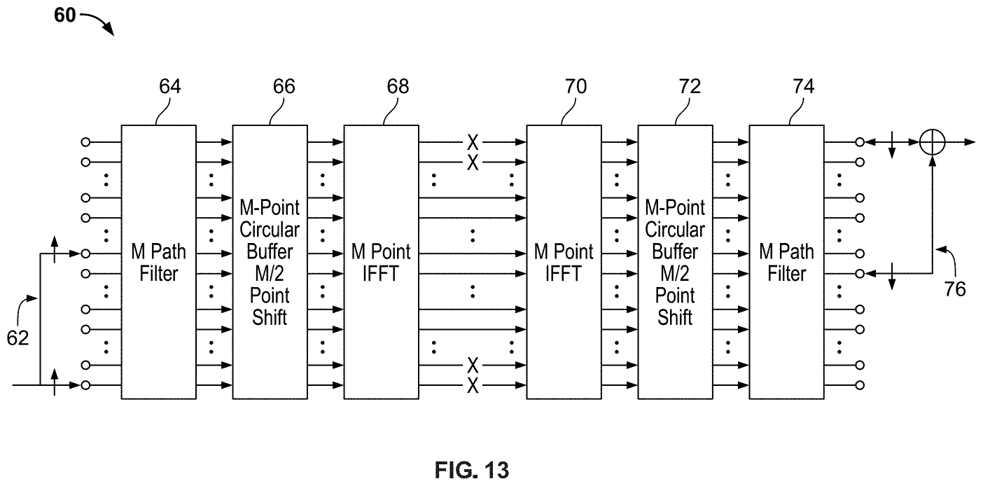

A third option for the half band filter is the cascade of a pair of analysis and synthesis channelizers. The analysis synthesizer partition the input spectrum into a set of reduced sample rate baseband channels. The prototype filter in the analysis channelizer is Nyquist filter designed so adjacent channels cross at their −6 dB levels. The synthesis channelizer performs the perfect reconstruction of these baseband channels as they are aliased up to their original center frequencies by the M/2 up-sampling process. The bandwidth filtering option is performed by the binary mask between the analysis and synthesis banks. The stop band corresponds to the channels not participating in the assembly of the super channel formed by the channels passed to the synthesis process from the output of the analysis process. This architecture is shown in FIG. 13, which depicts a half-band filter 60 that includes cascaded channelizers. In particular, the filter 60 includes an input commutator 62, an M-path filter 64, an M-point circular buffer 66 that generates an M/2 point shift, a first M-point IFFT 68, a second M-point IFFT 70, a second M-point circular buffer 72 that generates an M/2 point shift, a second M-path filter 74, and an output commutator 76. The components 62-68 form the analysis channelizer, and the components 70-76 form a synthesis channelizer. We select the number of paths in the channel for which the channel transition matches the super channel's desired transition BW. We selected a 40 path system because the channel widths and spacing operating at 48 MHz is 48/40 or 1.2 MHz and the transition BW of the channelizer starts at ⅓ of the width or 0.4 MHz. We can adjust the transition BW with filter length and window main lobe width.

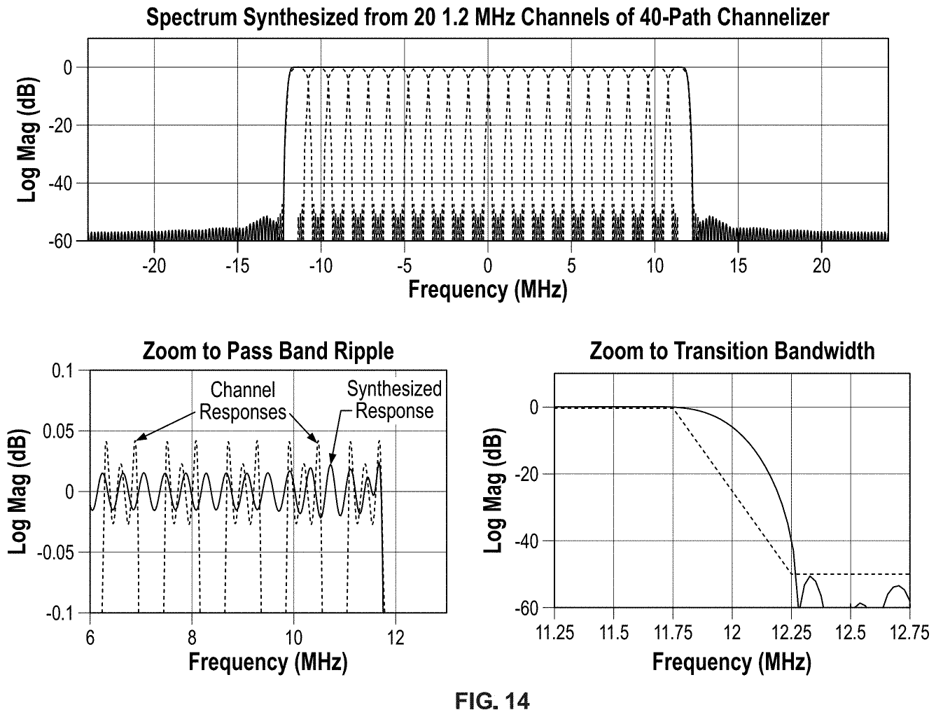

We designed the 40 path filter with 6-taps per path and synthesized the half band filter with 20 selected channels in an offset bin channelizer. The spectral characteristics are shown in FIG. 14. The computational workload for the synthesized filter is 12 multiplies per input sample, 12 multiplies per output sample for the path filters and 10 multiplies per input sample for the two 40 point IFFTs. When the output 40 path filter is replaced with a 20-path filter to reduce the output sample rate the workload for the output channelizes is cut in half for a combined workload of 25 multiplies per input sample.

It is noted that the various channelizers and filters disclosed herein could be implemented using any suitable processor such as an application-specific integrated circuit (ASIC), a digital signal processor (DSP), a field-programmable gate array (ASIC), a microprocessor, or as software executed by a general-purpose processor. It is additionally noted that the channelizers and filters could be implemented in a radiofrequency transceiver, which could include, but is not limited to, a cellular transceiver (e.g., base station or mobile device supporting one or more communications protocols such as 3GPP, 4G, 5G, etc.), a satellite transceiver (e.g., an earth station or a satellite in space), a wireless networking transceiver (e.g., a WiFi base station or WiFi-enabled device), a short-range (e.g., Bluetooth) transceiver, or any other radiofrequency transceiver.

Advantageously, the channelizers and filters disclosed herein meet a severe set of specifications, such as operation at high sample rate fₛ with specifications that lead to very long filter lengths. Fortunately, the M-path polyphase channelizer performs M-to-1 down sampling to each of the M-paths. This means that each path operates at the reduced sample rate fₛ/M. Two filters can be implemented, one operating at the high input sample rate and one operating at the lower output sample rate. In this process, the first filter, with a wider transition bandwidth, reduces the bandwidth and sample rate.

Having thus described the system and method in detail, it is to be understood that the foregoing description is not intended to limit the spirit or scope thereof. It will be understood that the embodiments of the present disclosure described herein are merely exemplary and that a person skilled in the art can make any variations and modification without departing from the spirit and scope of the disclosure. All such variations and modifications, including those discussed above, are intended to be included within the scope of the disclosure. What is desired to be protected by Letters Patent is set forth in the following claims.

What is claimed is:

1. A high-performance channelizer, comprising:
a digital direct synthesis (DDS) module generating a heterodyne signal;
a mixer in communication with DDS module and mixing the heterodyne signal with an input signal; and
an M-path channelizer in communication with the mixer, the M-path channelizer processing an output signal of the mixer to generate a plurality of output channels,
wherein the heterodyne signal shifts an input spectrum of the input signal by an offset between input and output centers.

2. The channelizer of claim 1, wherein the heterodyne signal operates at a high input sample rate.

3. The channelizer of claim 1, wherein the channelizer is implemented using one or more of an application-specific integrated circuit (ASIC), a digital signal processor (DSP), a field-programmable gate array (ASIC), a microprocessor, or software executed by a general-purpose processor.

4. The channelizer of claim 1, wherein the channelizer is implemented in a radiofrequency transceiver including one or more of a cellular transceiver, a satellite transceiver, a wireless networking transceiver, or a short-range transceiver.

5. A high-performance channelizer, comprising:
an input commutator receiving and commutating an input signal;
an M-path polyphaser filter in communication with the commutator; and
an M-path inverse discrete Fourier transform module processing outputs of the polyphaser filter,
wherein the M-path polyphaser filter introduces a plurality of phase rotations in a time domain resulting in a workload reduction for a processor on which the channelizer is implemented.

6. The channelizer of claim 5, wherein the plurality of phase rotations are inserted at a rate of 1/30th of an input rate of the channelizer.

7. The channelizer of claim 5, wherein the channelizer is implemented using one or more of an application-specific integrated circuit (ASIC), a digital signal processor (DSP), a field-programmable gate array (ASIC), a microprocessor, or software executed by a general-purpose processor.

8. The channelizer of claim 5, wherein the channelizer is implemented in a radiofrequency transceiver including one or more of a cellular transceiver, a satellite transceiver, a wireless networking transceiver, or a short-range transceiver.

9. A resampling channelizer, comprising:
a frequency division multiplex (FDM) commutator receiving and commutating an FDM input signal;
an M/2-path input data buffer in communication with the FDM commutator;
an M-path polyphaser filter in communication with the input data buffer;
a circular output buffer in communication with the M-path polyphaser filter;
an M-point inverse fast Fourier (IFFT) module in communication with the circular output buffer; and
a time division multiplex (TDM) commutator in communication with the M-point IFFT module and generating a TDM output signal,
wherein the M-path polyphaser filter is operated at a sample rate above fₛ/M.

10. The channelizer of claim 9, further comprising a state engine in communication with and controlling the FDM commutator and the circular output buffer.

11. The channelizer of claim 9, wherein the channelizer is implemented using one or more of an application-specific integrated circuit (ASIC), a digital signal processor (DSP), a field-programmable gate array (ASIC), a microprocessor, or software executed by a general-purpose processor.

12. The channelizer of claim 9, wherein the channelizer is implemented in a radiofrequency transceiver including one or more of a cellular transceiver, a satellite transceiver, a wireless networking transceiver, or a short-range transceiver.

13. A half-band filter, comprising:
an upper filter path including even indices of a low-pass filter;
a lower filter path including even symmetric filter coeeficients;
a switch in communication with the upper and lower filter paths and switching an input signal between the upper and lower filter paths; and
a mixer in communication with the upper and lower filter paths and mixing outputs of the upper and lower filter paths.

14. The filter of claim 13, wherein the filter is implemented using one or more of an application-specific integrated circuit (ASIC), a digital signal processor (DSP), a field-programmable gate array (ASIC), a microprocessor, or software executed by a general-purpose processor.

15. The filter of claim 13, wherein the filter is implemented in a radiofrequency transceiver including one or more of a cellular transceiver, a satellite transceiver, a wireless networking transceiver, or a short-range transceiver.

16. A cascaded half-band filter, comprising:
an input commutator receiving and commutating an input signal;
a first M-path filter in communication with the input commutator;
a first M-point circular buffer in communication with the first M-path filter;
a first M-point inverse fast Fourier transform (IFFT) module in communication with the first M-point circular buffer;
a second M-point IFFT module in communication with the first IFFT module;
a second M-point circular buffer in communication with the second M-point IFFT module;
a second M-path filter in communication with the second M-point circular buffer; and
an output commutator in communication with the second M-path filter and generating an output signal,
wherein the input commutator, the first M-path filter, the first M-point circular buffer, and the first M-point IFFT module form an analysis channelizer, and the second M-point IFFT module, the second M-point circular buffer, the second M-path filter, and the output commutator form a synthesis channelizer, the analysis channelizer cascaded with the synthesis channelizer.

17. The half-band filter of claim 16, wherein the analysis channelizer partitions the input signal into a set of reduced sample rate baseband channels, and the synthesis channelizer reconstructs the baseband channels.

18. The half-band filter of claim 17, wherein the baseband channels are aliased up to their original center frequencies by an M/2 up-sampling process.

19. The half-band filter of claim 16, wherein the filter is implemented using one or more of an application-specific integrated circuit (ASIC), a digital signal processor (DSP), a field-programmable gate array (ASIC), a microprocessor, or software executed by a general-purpose processor.

20. The half-band filter of claim 16, wherein the filter is implemented in a radiofrequency transceiver including one or more of a cellular transceiver, a satellite transceiver, a wireless networking transceiver, or a short-range transceiver.
